(19) United States
(12) Patent Application Publication
(10) Pub. No.: US 2011/0125433 A1
(43) Pub. Date: May 26, 2011

(54) BATTERY MANAGEMENT SYSTEM

(76) Inventors: Tim Schaefer, Niedersachswerfen (DE); Thomas Timke, Syke (DE); Andreas Fuchs, Leipzig (DE)

(21) Appl. No.: 12/867,098

(22) PCT Filed: Feb. 18, 2009
(86) PCT No.: PCT/EP09/01120

§ 371 Date: Feb. 4, 2011

(30) Foreign Application Priority Data
Feb. 20, 2008 (DE) 10 2008 009 970.8

(51) Int. Cl. G01R 31/36; G01N 27/416; H02J 7/04; H03K 17/00

(52) U.S. Cl. 702/63; 324/426; 320/134; 307/112

(57) ABSTRACT

Control apparatus for operating a rechargeable energy storage device and for collecting operating data, as well as a method for operating such a control apparatus. The invention is described with reference to the use in a motor vehicle and to the control of the rechargeable energy storage device thereof for the supply of the electric drive of the motor vehicle. However, it should be noted that an apparatus having the features of the claims can operate rechargeable energy storage devices also independently of motor vehicles, or in stationary use.

The present invention relates to a control apparatus for operating a rechargeable energy storage device and for collecting operating data, as well as a method for operating such a control apparatus. The invention is described with reference to the use in a motor vehicle and the control of the rechargeable energy storage device thereof for the supply of the electrical drive of the motor vehicle. However, it should be noted that an apparatus with the features of the claims can operate rechargeable energy storage devices also independently of motor vehicles, or in stationary use.

Control apparatuses for rechargeable energy storage devices consisting of galvanic cells are known from the prior art. Such apparatuses control, for example, the charging/discharging of attached galvanic cells and possibly engage with these operations in order to eliminate undesired states of single cells. To this end, usually electrical voltages, temperatures and/or states of charge of attached galvanic cells are determined and evaluated. Subsequently to an evaluation, these known control apparatuses engage with some operations in a corrective way if necessary.

Here, such control apparatuses are not capable with respect to their requirements of collecting sufficient information about the operating states of a rechargeable energy storage during its use which information serve the support of diagnostic operations and the prediction of a remaining lifetime of the operated energy storage device.

It is the object of the present invention to collect sufficient data during the use of a rechargeable energy storage and to compile analyses for the support of diagnostic operations and for the prediction of a remaining lifetime of the energy storage. This object is achieved by a control apparatus and a method of operation thereof according to the features of the claims.

The invention relates to a control apparatus for operating a rechargeable energy storage device. This rechargeable energy storage device has at least one galvanic cell for storing electrical energy. This rechargeable energy storage device is dedicated in particular to the supply of an electrical drive of a motor vehicle. This control apparatus is characterized in that it has at least one control device for the controlled operation of an attached galvanic cell. Additionally, this control apparatus has a measuring device which is capable of determining at least one functional parameter of at least one attached galvanic cell. Furthermore, this control apparatus has an analyzing device for analyzing at least one measured functional parameter of this at least one attached galvanic cell. Additionally, the control apparatus has a first storage unit for depositing data. These data comprise at least this measured functional parameter or an entity derived therefrom, whereby a value is stored together with this entity revealing the point of time of the measurement.

According to the main claim, the rechargeable energy storage device has at least one galvanic cell. However, it is by all means possible that several galvanic cells in different kinds of connection (serial and/or parallel connection of these cells) form this rechargeable energy storage device. The control apparatus according to the invention is also capable of operating energy storages designed in this way.

A so-called galvanic cell has at least a first and a second device for storing electrically different charges and a means of establishing an electrically functional connection of said two devices, charge carriers being shiftable between said two devices. The means of establishing an electrically functional connection is defined, for instance, as a so-called electrolyte, acting as an ion conductor.

Said measuring device is defined as a device for collecting a functional parameter of a galvanic cell. In the present case, these are, for example, devices for measuring electrical entities, e. g. electrical voltage, electrical current, electrical charge, but also the temperature of a galvanic cell.

Functional parameters are defined as such physical entities which can serve to describe a galvanic cell. These are, for example, the electrical capacity of such a cell, the electrical voltage which is measurable between the two poles of this cell in an off-load operation or as a load-dependent terminal voltage, the strength of an electrical current leading to a charge or discharge, the inner resistance of a galvanic cell, which technical voltage sources are normally afflicted with, the electrical charge of the galvanic cell which has already been charged or is available, leakage currents between the poles within this galvanic cell, or the temperature of the cell, which is possibly only measured from the outside for practical reasons. Depending on the requirements for the operation of such a rechargeable energy storage device, also other physical entities can be of interest.

Said analysis device, for instance, serves to make a measured functional parameter available for further processing by this first control device. For example, not all measuring devices provide an electrical voltage as a result. For instance, a charging or discharging current must be transformed into a proportional voltage. This is also true for a measured temperature, if necessary.

The control apparatus further has a first storage unit. This first storage unit serves to store measured functional parameters or entities derived from them, as for example corresponding integrated or differentiated values. Together with these values, a temporal assignment is stored, so that one can also temporally retrace the operations in the galvanic cells later.

The control apparatus is capable of monitoring the temporal development of a functional parameter. A measured and analyzed functional parameter is compared to a target value for this functional parameter. This is done computationally by forming a difference between the analyzed and the given value (target value). This first control device retrieves the target value needed for this from this first storage unit. Determined differences of present and intended values (target value) of this functional parameter are used for evaluating the state of the rechargeable energy storage device.

Depending on these calculated differences, this first control device can consider it necessary to choose one or more measures from a group of given measures for reducing these calculated differences due to a set of rules which has been provided to it for observation and which has been stored in this first assigned storage unit. It is intended that a functional parameter of a galvanic cell is transferred back into a desired range by such a measure taken. For example, this first control unit can turn on a cooling or extinguishing device.

It might possibly happen that one or more measures initiated by the first control device for transferring a functional parameter back into a target range do not lead to the desired result. In these cases, in which these calculated differences cannot be reduced as desired, this first control device can turn off the galvanic cell which is in an undesired state or can disconnect the input leads thereof. This is virtually the last measure which is available to the first control device which is intended to serve to avoid a possible damage to this rechargeable energy storage device or the control apparatus operating it.

This first control device is capable of computationally compiling a retrospective temporal development of an arbitrary functional parameter of an arbitrary galvanic cell. The first control device will compare this temporal development to a predetermined development if required, this predetermined development of a functional parameter being stored in the first storage unit. The results of such a comparison can in turn be stored in this first storage unit. These comparisons and their evaluations can support a diagnosis of an operational incident conducted if required. An expert can get insights related to temporal sequences of events and developments of single functional parameters from such developments.

For a skilful person, in particular the knowledge of the temperature or of the state of charge of a galvanic cell can be important. Therefore, this first control device can be involved in particular in the control of the temperature of a cell or of the state of charge thereof. The state of charge is defined as physical entities like the constructional electrical capacity of a cell, the actually yieldable electrical holding capacity of a cell, a voltage which is currently measurable between the poles of a cell and others. In order to counteract an undesired temperature of a galvanic cell, this first control device can, for example, turn a cooling device on or off. Undesired states of charge can be counteracted by shifting charges between, for instance, adjacent galvanic cells. For example, a charging process of a galvanic cell is disrupted or aborted, or a galvanic cell is at least partially discharged via a resistor.

A computing instruction is stored in this first storage unit, allowing this first control device to deduce the future development of a functional parameter from its measured development. This computing instruction can be a simple extrapolation modeling the physics of the cell just in an insufficient way, or an instruction which is better adapted to this physics. With the help of a prediction of a functional parameter, the undesired development thereof can be prevented by timely initiating corrective actions. In this way, for example, accumulative damages to galvanic cells operated in this way can be reduced. Thus, their lifetime is increased. In particular, the prevention of undesired temperatures or states of charge can act in a manner prolonging the lifetime.

In the following, a computing instruction for determining the temperature of a galvanic cell is stated as an example. The temperature of a galvanic cell depends on the design thereof and the conditions of use. It is assumed that the temperature of a cell is influenced by the interaction of a heat stream from the environment \dot{Q}_{∞}(at least natural convection) and an electrical heating power P_{E} from the charging or discharging current. This results from a heat stream balance with respect to the galvanic cell. The approximation sign ≈ indicates that it is an idealized relationship.

Cₚ\dot{T}≈\dot{Q}_{∞}+P_{E}=−k*A*ΔT+I²*R

Here, Cₚ stands for the heat capacity of the cell, \dot{T} for its temperature gradient, k for the heat transition coefficient regarding the heat stream through the cell wall, A stands for the surface thereof, ΔT stands for the temporally variable difference of the ambient and the cell temperature, I stands for the temporally variable charging or discharging current and R for the electrical resistance of the cell. This differential equation must be solved using the boundary and initial conditions of the operation of the galvanic cell. One obtains a first mathematical model of the cell temperature as a function of time.

In practice, the use of the above-mentioned mathematical model is impeded by deficiencies of the measurement of the current cell temperature and the presence of transient and multi-dimensional heat conduction. Empirical values for the adaptation of the above-mentioned computing instruction to the real cell can be gained from laboratory use. A mathematical temperature model improved in this way allows a prediction of the cell temperature with significantly smaller errors.

The temperature model used can be adapted from time to time for yielding an even higher precision. Results and insights from further laboratory measurements can serve this purpose, in which case the temperature model would be substituted, for example, in the course of maintenance processes. However, the temperature model can also be designed as a self-learning model due to the observation of operational states by means of an installed control loop.

The behavior of a galvanic cell changes as the aging of the cell advances, so that, for example, an unchanged charging process leads to a reduced charge or available voltage of the cell. If the standards with respect to the precision of the prediction are high, an adaptation of the model is necessary.

The above-mentioned methods for the development of a temperature model can also be applied to other functional parameters, for example to the stored electrical charge of a galvanic cell or the electrical voltage thereof. A balance with respect to electrical current, for example, serves as a starting point for the development of the model. Furthermore, there is a relation between the thermal and the electrical behavior of a galvanic cell via the electrical heating power.

It is advantageous to work out a mathematical modeling of the electrical or thermal behavior of a galvanic cell on the basis of a given embodiment. For instance, the mathematical model of the thermal behavior can be amended by terms and adjusting factors accounting for the multi-dimensional and transient heat transition through a wall of one or more galvanic cells. Something similar applies to a mathematical model of the electrical behavior of one or more cells. Adjusting factors of such models need to be adapted from the comparison with the actual thermal behavior.

The given embodiment has to be exposed to all kinds of different operational states in the laboratory corresponding to the likely boundary and use conditions of the rechargeable energy storage devices. Operational schedules for covering possible parameter values as, for example, temperature, state of charge and state of aging of the cell have to be drawn up. Here, the use of parameter estimation algorithms can serve to determine the range of fluctuation of an arbitrary parameter and thus to verify or, if required, to expand the operational and measurement schedules.

Laboratory operation of a given rechargeable energy storage device with the battery management system according to the invention can, just like the collection of measurement data, be done in an automated (computer-supported) way, serving to increase the repetition accuracy of the trials. In laboratory operation, the instrumentation or sensoric equipment can be chosen more extensively than it is envisaged for an economical series-production use later on. In laboratory operation, one can put a strain on the rechargeable energy storage device with a manageable risk even beyond and outside operational conditions according to the requirements. Especially this mode of operation leads to a gain of insight and can serve as a basis for the development of remedy measures.

In laboratory operation, the operating conditions or the instrumentation (sensoric equipment) can be adapted to gained insights at short notice if required. Gained measurement data can also serve to review a mathematical model at short notice. In the laboratory, a stepwise and rapid refinement of the mathematical models is possible.

If state entities or functional parameters of a galvanic cell are not measurable or measurable just with difficulties or, for example, one has to do without certain transmitters due to cost reasons, then the development of a state observer can be helpful. A developed state observer can accomplish the entirely mathematical description of the control loop consisting of the different control devices of the battery management system, the sensors and the operated rechargeable energy storage device.

A mathematical model of the control loop which has been designed with respect to the electrical and thermal behavior of a galvanic cell, or an arrangement of such cells, with adaptation factors, is instructed to predict operational states. This simulation is done in a computer-supported way, using measurement data which have been collected before. At first, the state observer will predict the behavior of the embodiment just in an insufficient way and will review the adaptation factors of the underlying model using the determined difference between the calculated prediction by the model and the actually measured parameter. As the number of comparisons of predictions to occurred states advances, the mathematical model will get closer and closer to the behavior of the real control loop. Eventually, one can obtain a tuned-in and sufficiently precise mathematical representation of the processes and a model for the prediction of states.

Starting at an instrumentation of the galvanic cell which is nearly complete at first, the number of sensors used can gradually be reduced. As long as the common mathematical model of the control loop is tuning in, a further sensor can be removed for the next iteration. It is up to the expert how much he wants to trade off a stable and redundant controlling behavior against cost savings.

A state observer can be operated in a battery management system according to the invention or can be refined at first and can be queried during maintenance activities.

The first control device determines the future storable electrical charge and/or extractable electrical charge and/or the highest achievable electrical voltage and lowest electrical voltage of galvanic cells from determined temporal developments of functional parameters in future by means of one further computing instruction each. Thus, a statement about the further operation of the rechargeable energy storage device becomes possible. Knowing the functional parameters arising in future, also the advancing aging of the energy storage device can be detected and an economical remaining lifetime can be predicted. Thus, for example, a required maintenance can be signaled.

A said first control device is dedicated to the operation of, for instance, a serial connection of some galvanic cells. For complementing it, the control device according to the invention can have a second control device with a corresponding second storage unit. A task of this second control device is the monitoring of an energy supply for operating the control apparatus according to the invention. For example, a supply voltage too high can be limited by an electrical circuit of the second storage unit, or a supply voltage too low can be compensated by a voltage pump contained in the second control device or the like.

This first and this second control device are signal-connected to each other, i. e. they are capable of exchanging signals and data. Electrical lines, optical lines or a wireless connection can serve this purpose. The signal exchange is done in either direction and serves different purposes. A first regular exchange between these two control devices serves to ascertain that the respective other control device works properly (“first sign of life”). For this purpose, predetermined signals can be sent and received regularly or irregularly following a predetermined time schedule. However, it is also possible to offer a static entity to the respective other control device to be queried. Other devices or methods which are common in this field can serve this purpose too. It is signaled by this virtual assurance of the first and the second control device that a control device can expect a desired behavior of the partner with high probability. In particular, the deployment of a rechargeable energy storage device in motor vehicles requires this mutual assurance. It is by all means possible to use other kinds of mutual assurance, for example by prescribed methods of the automotive industry.

The proper function of the two said control devices is necessary in order to ensure the safe operation of a rechargeable energy storage unit or the proper drive of a motor vehicle. If this first sign of life should not be properly received by the receiver determined for this, then a malfunction has to be assumed. The control devices are arranged to activate an electrical switching device if the first sign of life fails to appear. Uncontrolled discharging of the rechargeable energy storage unit is prevented by activating this electrical switching device. For example, the input lead to this electrical energy storage unit can be disrupted by activating this electrical switching device.

Depending on measured and analyzed functional parameters of a galvanic cell, the first control device sends predetermined signals to this second control device on a regular basis or if required. These signals give information about desired or undesired values related to physical entities, about desired or undesired temporal developments of functional parameters or about the presence of certain operational states or messages related to initiated or terminated corrective actions or messages of an active software for acknowledging the proper function. This second control device receives these messages and stores them together with a time information in the second storage unit. A protocol related to events or assertions is generated in the second storage unit by these entries.

The second control device is arranged in such a way that it can read or overwrite contents of a first storage unit. Thus, the second control device is capable, if required, to determine or to query values or developments related to functional parameters or determined deviations. For example, this serves the support of a diagnostic process. If required, the second control device is also capable of specifying target values or predetermined developments of functional parameters for a first control device or to change specifications. This is also true for the specification of limit values which can depend on the respective operational state of the rechargeable energy storage unit. It is reasonable, for instance, to limit charging or discharging currents of galvanic cells in dependence of the temperature of a galvanic cell. This can serve the prevention of accumulated damages and thus the prolongation of the lifetime of the rechargeable energy storage unit. It can also be useful to specify minimum or maximum voltages of galvanic cells. For example, a change of charge of galvanic cells has to be done within narrower limits in winter.

In case the measures for recovering the adherence to a target value of a functional parameter initiated by a first control device remain without success, this second control device is arranged for activating an electrical switching device. This serves to increase the operational safety of a rechargeable energy storage unit, for example when a first control device fails. In particular, an excessively high discharging current of a galvanic cell or a sudden voltage decrease of a galvanic cell can indicate a fault. Both the rechargeable energy storage unit and the supplied drive unit of a motor vehicle have to be protected from such faults. For instance, this second control unit can turn a cooling or extinguishing device on.

Because of constraints due to manufacture or operation, certain serial and/or parallel connections of galvanic cells are desirable. Here, it can be useful to form packets of galvanic cells in serial connections for reaching a desired electrical voltage first. If a larger charge is to be carried along, then a parallel connection of such packets is reasonable. The control apparatus according to the invention is capable of operating such arrangements too. Depending on the design of the rechargeable energy storage unit, it is advantageous that a second control device is connected to several first control devices. In particular, this is advantageous with groups of galvanic cells connected in parallel for increasing the capacity or the holdable charge. With such an arrangement of control devices, this second control device can compensate possibly occurring different states of charge between the single groups of galvanic cells, each of which is monitored by one first control device. This measure can serve to distribute the retrieval or storage of electrical charges to these different groups of galvanic cells in a more uniform way. This approach can increase the lifetime of the rechargeable energy storage unit.

Due to its exposed position, a second control device is capable of comparing temporal developments of several functional parameters of different galvanic cells which can also be assigned to different first control devices. These determined developments can also be compared to globally predetermined developments of functional parameters stored in this second storage unit. By means of a computing instruction which is also stored in this second storage unit, the second control device is capable of identifying a change of available capacities of galvanic cells in the course of the advancing lifetime thereof. Such a global functional parameter can also be the electrical voltage which can be measured across the entire rechargeable energy storage unit. A reasonable remaining lifetime of the rechargeable energy storage unit can be determined from such global functional parameters by means of a deposited computing instruction.

This second control device can be signal-connected to an external control for carrying out a scheduled or unscheduled maintenance activity. This signal connection can, as described before, be designed in a wired or wireless way. This second control device and the external control are arranged in such a way that they can exchange predetermined signals via the signal connection. Furthermore, the second control device is arranged in such a way that it can provide the external control with access to the second storage unit, for instance for accessing compiled protocols. The second control device can also overwrite the contents of the second storage unit assigned to it, subject to the external control. Thus, computing instructions, new specifications for functional parameters or developments thereof as well as other deposited storage contents can be overwritten. For securing these storage contents, it is necessary that this external control authenticates itself against the second control device. Here, it is common to transmit or query, resp., security codes. A wired signal connection is to be preferred for security reasons.

A second control device is capable of rearranging the groups of galvanic cells assigned to a first control device each, depending on the state of these groups, if required. For example, existing serial and/or parallel connections of such groups of galvanic cells can be changed with the help of a suitable switching device. This can become necessary during the operation of this rechargeable energy storage unit, if, for example, individual first control devices have been switched off. The desired global voltage can still be guaranteed in the case of a reduced capacity by a suitable connection of these groups of galvanic cells. To this end, this second control device controls an electrical switching device. Thus, the drive system of the motor vehicle can be supplied albeit over a shorter period of time, but still with the required electrical voltage.

This second control device is signal-connected to a further control, for example during the use in a motor vehicle, this further control being assigned to the motor vehicle. The second control device and the further control can transmit signals to and receive signals from the respective other control device or control over the signal connection. Depending on a measured or an analyzed functional parameter of one or more galvanic cells, this second control device can send predetermined signals to this further control. These predetermined signals inform the further control about the operational state of the rechargeable energy storage unit.

This second control device and the further control can be connected within the motor vehicle over an arbitrary communication bus. This accounts for the different requirements of the different motor vehicle manufacturers. For example, this communication bus can be a CAN bus.

The second control device and this signal-connected further device exchange a predetermined signal over this signal connection at least intermittently regularly or irregularly. This signal serves to reassure the receiver that the sender works properly. This signal is called second sign of life.

When this second sign of life fails to appear, this second control device or this further device can activate an electrical switching device, this activation depending on the operational state of this motor vehicle. These features serve to increase the operational safety of the rechargeable energy storing unit and enable the second control unit, which is working properly, or this further control to prevent the rechargeable energy storage unit from discharging in a possibly uncontrolled way. As above, several cascaded measures are available for this purpose, in which context also a disruption of the input leads to the rechargeable energy storage unit can be induced. The operational state of the motor vehicle serves as a further determining factor for taking these measures. When the motor vehicle is non-operative, the second control device can possibly do without taking these measures. This is the case when a current retrieved from the rechargeable energy storage unit does not exceed a predetermined value. When the motor vehicle is operative and the further control is functional, an activation of a switching device can possibly remain undone. This behavior cannot be specified in a universally valid way and is also co-determined by the user or the manufacturer of the motor vehicle.

In special cases, for example during a car accident or immediately afterwards, this further control can send a predetermined signal to this second control device which informs this second control device about an emergency which has occurred. After receiving this emergency signal, this second control device activates an electrical switching device for disrupting the input leads to the rechargeable energy storage unit or with at least one other consequence stipulated by the user or the manufacturer of the motor vehicle.

This control apparatus according to the invention can be used for the operation of rechargeable energy storage units according to different designs. It is advantageous to use this control device for rechargeable energy storage units which have a high power density and whose lifetime is significantly increased by ensuring the operation within predetermined limits. This is the case in particular with rechargeable energy storage units in which the electrolyte of the galvanic cells forming the rechargeable electrical energy storage unit has suitable electrical charge carriers. These electrical charge carriers serve to increase the cell voltage compared to rechargeable energy storage units with a low power density. For example, this is true for rechargeable energy storage units using lithium ions as electrical charge carriers.

The control apparatus according to the invention is operated in such a way that its first control device controls the existing measuring devices for collecting values related to functional parameters. In practice, a multitude of functional parameters of a galvanic cell are collected nearly simultaneously with a collecting clock of some kHz and are stored in an intermediate memory. This first control device also controls the existing analyzing devices. The data of the intermediate memory are filtered by the existing analyzing devices using computing instructions, are transformed into entities which are suitable for comparisons or are processed in another way. Functional parameters which are changing only slowly are, for example, temporally densified. This first control device also controls storing the processed data in this first storage unit and adds respective time information. In this way, a development protocol relating to the different functional parameters of the attached galvanic cells is created in this first storage unit.

This first control device determines the temporal changes of the values of a functional parameter in future from the values related to this functional parameter stored in this first storage unit, using a computing instruction. In a comparison to a predetermined development related to this functional parameter, this first control unit determines deviations, if required, which become larger and larger as the aging of the corresponding galvanic cell advances. For example, this concerns the relationship between applied charge as a product of charging current and charging time on the one hand and the achieved electrical voltage of the cell on the other hand. When the age of the cell increases, a smaller electrical voltage is reached with an unchanged charging process. When a smallest electrical voltage or charge to be achieved is under-run, an electrical drive system cannot be properly supplied anymore, and the respective cell must be changed. When different limit values with respect to the smallest electrical voltage to be achieved are introduced, this first control unit already recognizes the incipient failure of the affected cell and can communicate it to this second control device.

This second control device and the first control devices connected to it are arranged according to the invention for the mutual exchange of signals. A first control unit sends predetermined signals to this second control unit on a regular basis or if required. For example, these are messages about occurred deviations of functional parameters, accordingly initiated measures and their success, progress messages of a software and/or error messages thereof. In this way, this second control unit is enabled to get an overview about the states of all galvanic cells of the operated rechargeable energy storage device. Thus, this second control unit compiles an accumulated protocol with time references, which is communicated to other receivers if required. Thereby, a certain data redundancy is created. Furthermore, the overview allows for advanced analyses, which can be relevant for diagnostic processes also after failures of individual groups, each consisting of one first control device and the galvanic cells thereof.

In the opposite direction, a second control device has access to the existing first storage units. This access serves, for example, to query target values stored therein or predetermined developments of functional parameters or to change them by overwriting the memory contents. This access is also used for adapting the operating profiles, for example of charging current developments, to changed constraints as, for example, ambient temperatures or advancing aging of the rechargeable energy storage device. In this way, a second control device can also replace computing instructions in existing first storage units, for example in the course of maintenance activities or updates of the software. It is also possible for a temporarily signal-connected external control instead of this second control device, for instance a diagnostic apparatus or a charging device, to proceed in this way.

A group, consisting of a first control device and the galvanic cells thereof, can fail, for example because the software of this first control device being executed is not working properly anymore, or if at least one of the attached galvanic cells behaves in an undesired way and the group was therefore turned off. In this case, the existing combination of parallel and serial connections of the groups of the rechargeable energy storage device can get into a state of imbalance with respect to the electrical voltage, for instance because a serial connection of groups cannot provide the required electrical voltage anymore due to a failed group. With the help of a switching device and by using a computing instruction, this second control device establishes a different serial and/or parallel connection of the groups for supplying the required electrical voltage, if necessary also during the use of the operated motor vehicle. In doing so, further groups are switched off if required or are electrically isolated by disrupting their input leads. Thus, it is possible to operate an electrical drive system when the overall capacity of the rechargeable energy storage device is reduced, the cruising range of the driven motor vehicle being reduced as well.

Depending on the respective operational state of the driven motor vehicle, uncontrolled discharge of the rechargeable energy storage device is also undesired. For example, the further and/or uncontrolled discharge of the rechargeable energy storage device has to be avoided immediately after an excessive acceleration of the rechargeable energy storage device. In such a situation, this further control sends a predetermined signal, which is received by this second control device as an indication of an emergency and understood. After this, the second control device cuts the input leads to this energy storage device or activates a switching device for preventing uncontrolled discharge.

In a further embodiment, the functions of the first and second storage units are united in a single storage unit. If required, a further storage unit which at least intermittently reads and stores a part of the storage content of this single storage unit is assigned to this single storage unit.

In a further embodiment, the functions of this second control device are fulfilled by a first control device. There is no separate second control device then.

In a further embodiment, the functions of this second control device are additionally accomplishable by a first control device, this first control device performing these functions only after a failure of this second control device.

### EMBODIMENT

Further advantages, features and application possibilities of the present invention follow from the subsequent description in connection with the figures, showing:

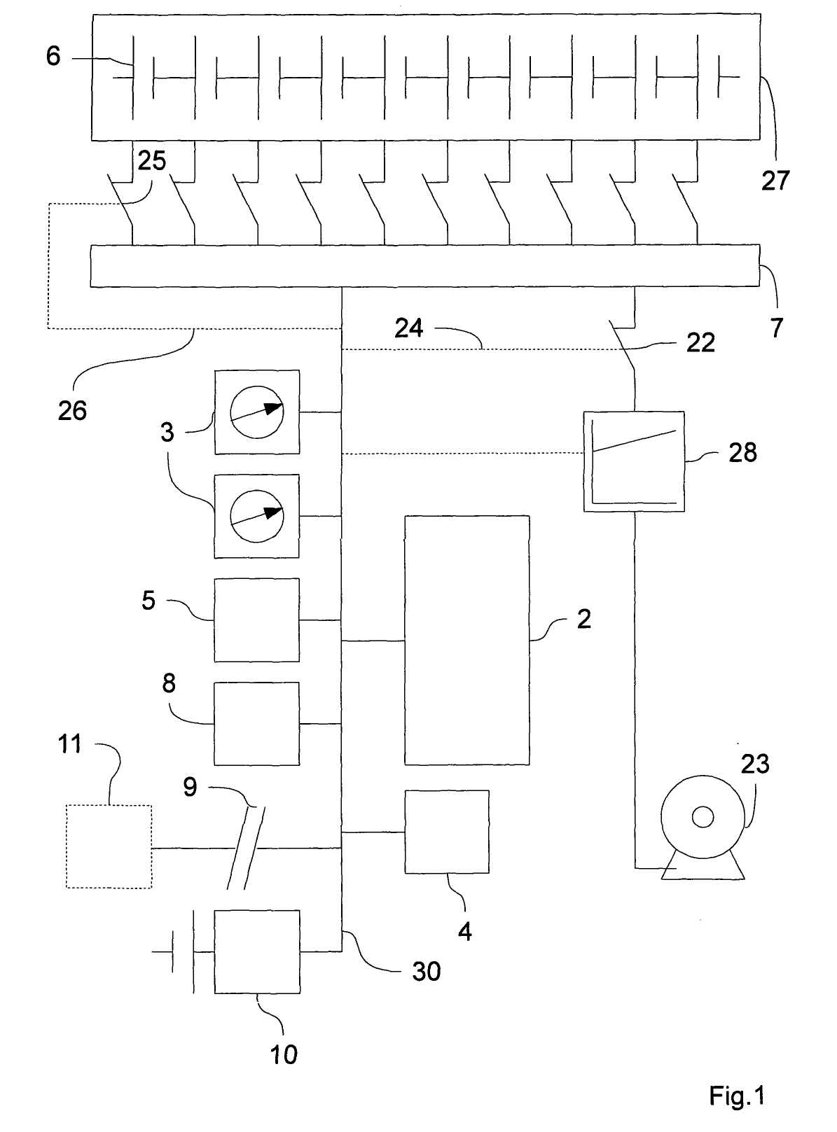

FIG. 1 A block diagram of a first control device of the control apparatus with further devices;

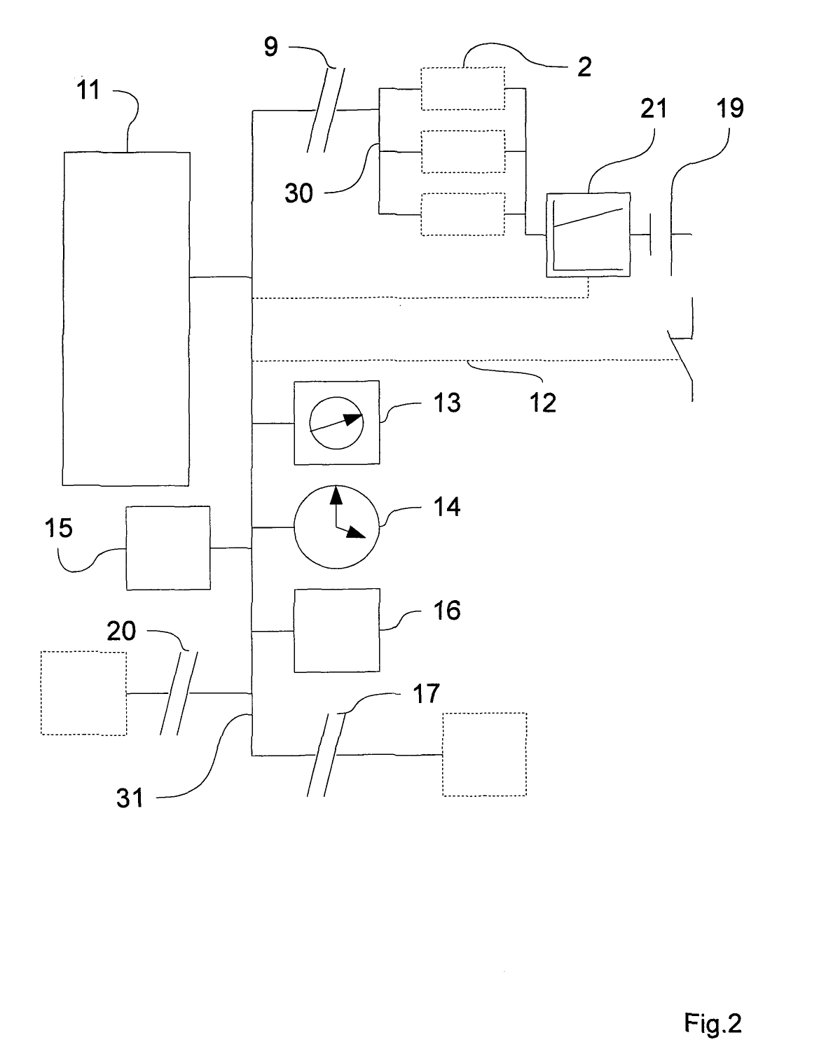

FIG. 2 A block diagram of a second control device of the control apparatus with further devices;

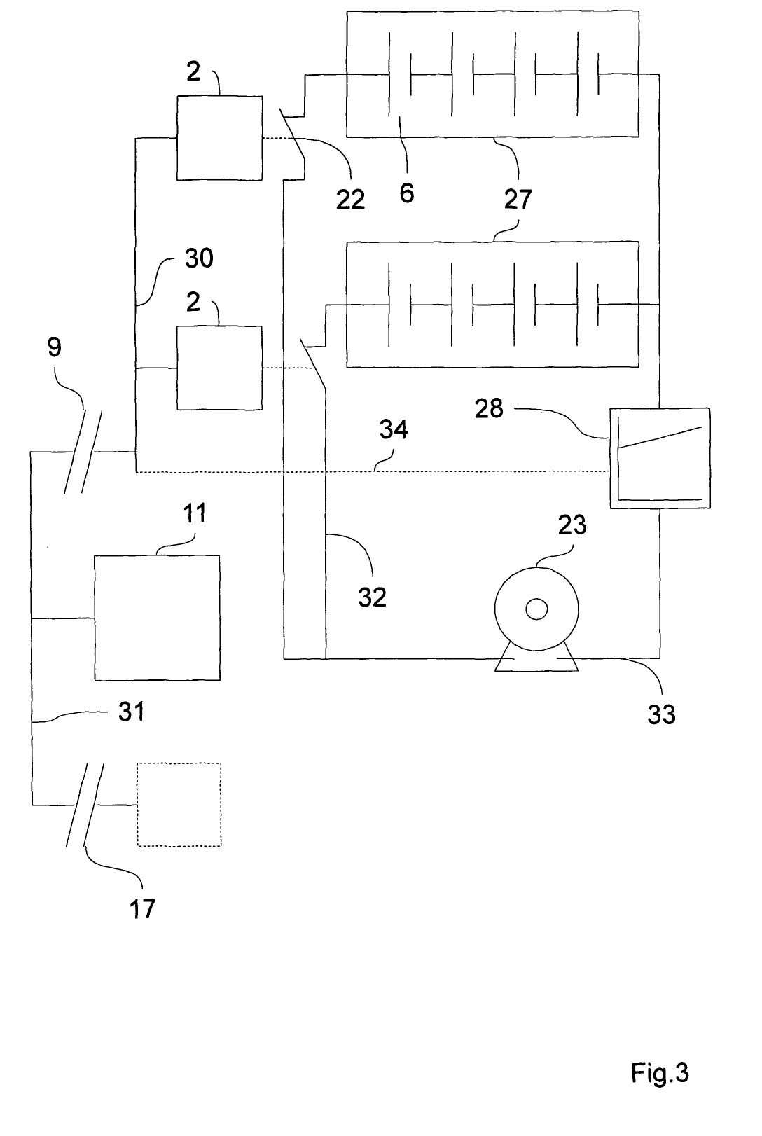

FIG. 3 A control apparatus for a rechargeable energy storage device with increased capacity, consisting of two groups of galvanic cells connected in parallel here.

FIG. 1 shows a first control device (2) of the control device (1) according to the invention. It is connected via a connection device (7) and respective switching devices (25) to the individual galvanic cells (6) of the rechargeable energy storage device (27). Apart from this first control device (2), at least one measuring device (3) is also connected to a first number of connection lines (30). The two measuring devices (3) shown serve the recording of the electrical voltage of a galvanic cell (6) and the temperature thereof. The analyzing device (4) is also connected to this first number of connection lines (30), transforming for further processing and processing, as described before, the recorded values related to the different functional parameters. This first control device (2) stores the processed values together with time information in a first storage unit (5). A state of charge compensation device (8) for compensating different states of charge of the attached galvanic cells (6) is also connected to the first number of connection lines (30). An electrical resistor via which a galvanic cell (6) can be discharged if required is not shown. This is in particular necessary when an individual galvanic cell (6), for example from a serial connection of galvanic cells (6), has a higher electrical voltage than the remaining cells. This electrical resistor, which is not shown, is connected by the state of charge compensation device (8) via the connection device (7) of the respective galvanic cell (6). A first interface (9) connects the first number of connection lines (30) to a second control device (11). Said electronic component units are supplied with energy via a control component (10). The electrical drive system (23) of the motor vehicle, which is connected to the connection device (7) via a control (28) and an electrical switching device (22), is also shown. When the switching device (22) is closed and a corresponding instruction is issued by this first control device (2), the electrical drive system (23) is supplied with electrical energy from the rechargeable energy storage device (27). A first control line (24), via which the first control device (2) can open a switching device (22) and thus disrupt the supply of the electrical drive system (23), is also shown. Opening the switch (22) is virtually the last measure which is available to the first control device (2) for preventing damages, for example due to uncontrolled discharge of a galvanic cell (6). Before this, a switching device (25), which would separate an individual galvanic cell (6) from the connection device (7), would be opened via a control line (26).

FIG. 2 shows a second control device (11) of the control apparatus (1). It is connected to the subsequent devices via a second number of connection lines (31). As stated above, this second control device (11) is connected to this first number of connection lines (30), which in turn is connected to the three first control devices (2) shown, via the first interface (9). The respective groups, represented by the respective first control device (2), are supplied with electrical energy from the voltage source (19) via a control device (21). A control line (12) to different switching devices is shown as an example. The recording component (13) serves the measurement of different currents, this measuring device being switchable into different circuits via a switching device (not shown) if required. A real-time clock (14) is also connected to the number of connection lines (31). It serves to provide time information, for example if a value or a message related to an event is to be stored in a storage unit. A second storage component (15), in which this second control device (11) creates an accumulative development protocol, is connected to the second number of connection lines (31). In this embodiment, a further storage component (16) serves to store software which is required for the operation of this second control device (11). Contents of the storage components (15, 16) can also be stored in a single storage component. Two further interfaces (17, 20), allowing this second control device (11) to exchange signals with a said further control assigned to the motor vehicle, and intermittently with an external control, for instance belonging to a diagnosis device, are also shown.

FIG. 3. shows a control apparatus (1) for a rechargeable energy storage device consisting, for example, of two groups. Such a group consists of one first control device (2) each and of an attached serial connection of four galvanic cells (6) each and of some further components which are not shown here. Two such rechargeable energy storage devices (27) are connected in parallel with the help of two input lines (32, 33). It is by all means possible, however, to connect a much larger number of energy storage devices (27) in parallel or in series. A control line (34), via which the control (28) is controlled, is part of the first number of connection lines (30). The second number of connection lines (31), allowing the signal exchange with a further control, in this case of the motor vehicle, via an interface (17), is also shown.

1. Control apparatus for operating a particularly rechargeable energy storage unit having at least one galvanic cell, the rechargeable energy storage unit being designated in particular for the supply of an electrical drive system of a motor vehicle, characterized in that the control apparatus comprises at least one first control device,
and a measuring device for measuring at least one functional parameter of at least one galvanic cell,
and an analyzing device for analyzing at least one functional parameter of the at least one galvanic cell
and at least one first storage unit, in order to store the functional parameter or an entity derived from the functional parameter preferably with at least one value which is representative of the point of time of the measurement.

2. Control apparatus according to claim 1, characterized in that the first control device monitors the adherence to a target value of at least one functional parameter of at least one galvanic cell, the target value of the functional parameter being stored in the first storage unit.

3. Control apparatus according to claim 2, characterized in that the first control device, in the case of a deviation of at least one functional parameter of a galvanic cell from a target value, initiates at least one measure for adhering to the target value and/or, if the initiated measure for recovering the adherence to a predetermined target value of a functional parameter of a galvanic cell was unsuccessful, turns the galvanic cell off.

4. Control apparatus according to claim 1, characterized in that the first control device determines a retrospective temporal development of a functional parameter from the measurement values of the functional parameter and compares the retrospective temporal development to a predetermined temporal development of the functional parameter which is stored in the first storage unit, and stores the result of the comparison in the storage unit as well.

5. Control apparatus according to claim 3, characterized in that the functional parameter is the temperature of a galvanic cell and the remedy measure is the turning on or off of a cooling device.

6. Control apparatus according to claim 3, characterized in that the functional parameter is the electrical voltage of a first galvanic cell and the remedy measure is the charging or discharging of the galvanic cell, at least one further galvanic cell of the rechargeable energy storage device, for example, delivering or absorbing the required charge.

7. Control apparatus according to claim 1, characterized in that the first control device determines a future temporal change of a functional parameter from a retrospective temporal change of this functional parameter, using a computing instruction stored in the first storage unit, and stores it in the first storage unit.

8. Control apparatus according to claim 1, characterized in that the first control device determines the advancing aging of the rechargeable energy storage device from a comparison of a determined future temporal change of a functional parameter of a galvanic cell to a corresponding predetermined temporal development of the functional parameter.

9. Control apparatus according to claim 1, characterized in that the control apparatus comprises a second control device and a second storage unit.

10. Control apparatus according to claim 9, characterized in that the first control device is signal-connected to the second control device and the first and the second control device are arranged for sending a signal to the respective other control device and/or for receiving a signal from the respective other control device.

11. Control apparatus according to claim 10, characterized in that the first control device and the signal-connected second control device exchange at least intermittently a predetermined signal, this signal being called a “first sign of life”.

12. Control apparatus according to claim 10, characterized in that the first control device sends predetermined signals to the second control device on a regular basis and/or if required, these signals being representative of measured and/or analyzed functional parameters of the attached galvanic cells,
and/or temporal developments related to these functional parameters, and/or deviations from target values or predetermined temporal developments of these functional parameters,
and/or messages related to operational states of the attached galvanic cells,
and/or messages related to started or terminated remedy measures,
and/or messages related to the execution of an active software of the first control device,
and the second control device stores these signals in the second storage unit, preferably with at least one value which is representative of the point of time of the measurement.

13. Control apparatus according to claim 11, characterized in that the first control device or the second control device activates an electrical switching device if a first sign of life has not been received.

14. Control apparatus according to claim 10, characterized in that the second control device is arranged for reading and/or overwriting the contents of a first storage unit, whereby, for example, operational profiles for charging and/or discharging processes, predetermined temporal developments of functional parameters, target values of functional parameters and/or computing instructions are read and/or overwritten.

15. Control apparatus according to claim 10, characterized in that the second control device activates an electrical switching device if an initiated measure for recovering the adherence to a predetermined target value of a functional parameter of a galvanic cell has been unsuccessful.

16. Control apparatus according to claim 10, characterized in that the second control device is signal-connected to several first control devices, at least one galvanic cell being assigned to each of these several first control devices, and such a combination of a first control device with the attached galvanic cells is called a group.

17. Control apparatus according to claim 16, characterized in that the second control device can compensate different states of charge of different galvanic cells by shifting charges between these different galvanic cells.

18. Control apparatus according to claim 16, characterized in that the control apparatus further has a switching device which is operated by the second control device, the switching device allowing for the electrical arrangement of the groups to each other as a parallel and/or serial connection or as combinations of these kinds of connections.

19. Control apparatus according to claim 10, characterized in the second control device is at least intermittently signal-connected to at least one external control and the second control and the external control are arranged for sending a signal to the respective other control device or control and/or for receiving a signal from this respective other control device or control.

20. Control apparatus according to claim 19, characterized in that the external control is arranged for reading and/or overwriting the contents of the second storage unit, whereby in particular computing instructions, operating profiles, messages related to operational states and/or predetermined temporal developments of functional parameters of the attached galvanic cells are read and/or overwritten.

21. Control apparatus according to claim 10, characterized in that the second control device is signal-connected to at least one further control and the second control device and the further control are arranged for sending a signal to the respective other control device or control and/or for receiving a signal from this respective other control device or control.

22. Control apparatus according to claim 21, characterized in that the second control device is signal-connected to the at least one further control via an arbitrary communication bus, the communication bus being, for example, a CAN bus.

23. Control apparatus according to claim 21, characterized in that the second control device and the signal-connected further control at least intermittently exchange a predetermined signal, this signal being called “second sign of life”.

24. Control apparatus according to claim 23, characterized in that the second control device activates an electrical switching device if a second sign of life has not been received, the motor vehicle being in an operational state.

25. Control apparatus according to claim 23, characterized in that the further control activates an electrical switching device if a second sign of life has not been received.

26. Control apparatus according to claim 21, characterized in that the further control sends a predetermined signal which is called “emergency signal” to the second control device and that the second control device activates an electrical switching device when the emergency signal has been received.

27. Control apparatus according to claim 1, characterized in that at least one galvanic cell of the rechargeable energy storage unit has a first and a second device for storing electrical charge and a means for an electrically functional connection of said devices for storing electrical charge, the means for the functional connection having electrical charge carriers which can be in particular lithium ions.

28. Method for operating a control apparatus according to claim 1 in particular for a rechargeable energy storage unit having at least one galvanic cell, the rechargeable energy storage unit being designated in particular for the supply of an electrical drive system of a motor vehicle, characterized in that at least one first control device of the control apparatus controls a measuring device for measuring at least one functional parameter of at least one galvanic cell and an analysis device for analyzing at least one functional parameter of the at least one galvanic cell and stores the functional parameter or an entity derived from the functional parameter preferably with at least one value which is representative of the point of time of the measurement in at least one first storage unit.

29. Method for operating a control apparatus according to claim 28, characterized in that the first control device determines the advancing aging of the rechargeable energy storage device from a comparison of a determined future temporal change of a functional parameter of a galvanic cell to a corresponding predetermined temporal development of the functional parameter, the measured electrical voltage of the galvanic cell, for example, being used as a functional parameter.

30. Method for operating a control apparatus according to claim 28, characterized in that the first control device sends predetermined signals to a second control device on a regular basis and/or if required, these signals being representative of measured and/or analyzed functional parameters of the attached galvanic cells,
and/or temporal developments related to these functional parameters,
and/or deviations from target values or predetermined temporal developments of these functional parameters,
and/or messages related to operational states of the attached galvanic cells,
and/or messages related to started or terminated remedy measures,
and/or messages related to the execution of an active software of the first control device,
and the second control device stores these signals in the second storage unit, preferably with at least one value which is representative of the point of time of the measurement.

31. Method for operating a control apparatus according to claim 28, characterized in that a second control device reads and/or overwrites the contents of a first storage unit, these contents being, for instance, operational profiles for charging and/or discharging processes, predetermined temporal developments of functional parameters, target values of functional parameters and/or computing instructions.

32. Method for operating a control apparatus according to claim 28, characterized in that a second control device operates a switching device for the electrical arrangement of groups, each group having a first control device and at least one galvanic cell, relative to each other as a parallel and/or serial connection or as combinations of these kinds of connection.

33. Method for operating a control apparatus according to claim 31, characterized in that an external control reads and/or overwrites the contents of the second storage unit, these contents being in particular computing instructions, operational profiles, messages related to operational states and/or predetermined temporal developments of functional parameters of the attached galvanic cells.

34. Method for operating a control apparatus according to claim 30, characterized in that a further control sends a predetermined signal, which is called “emergency signal”, to the second control device and that the second control device activates an electrical switching device when this emergency signal has been received.

35. Method for operating a control apparatus according to claim 30, characterized in that the first or second control device develops and/or operates a mathematical model of a control loop.

36. Control apparatus according to claim 8, wherein the functional parameter comprises the measured electrical voltage of the galvanic cell.

37. Control apparatus according to claim 18, wherein the functional parameter comprises the discharging current of the galvanic cell.

38. Control apparatus according to claim 2, characterized in that:
the first control device, in the case of a deviation of at least one functional parameter of a galvanic cell from a target value, initiates at least one measure for adhering to the target value and/or, if the initiated measure for recovering the adherence to a predetermined target value of a functional parameter of a galvanic cell was unsuccessful, turns the galvanic cell off;
the first control device determines a retrospective temporal development of a functional parameter from the measurement values of the functional parameter and compares the retrospective temporal development to a predetermined temporal development of the functional parameter which is stored in the first storage unit, and stores the result of this comparison in the storage unit as well, when the functional parameter is the temperature of a galvanic cell, the remedy measure is the turning on or off of a cooling device; and when the functional parameter is the electrical voltage of a first galvanic cell, the remedy measure is the charging or discharging of this galvanic cell, at least one further galvanic cell of the rechargeable energy storage device, for example, delivering or absorbing the required charge;
the first control device determines a future temporal change of a functional parameter from a retrospective temporal change of the functional parameter, using a computing instruction stored in this first storage unit, and stores it in this first storage unit;
the first control device determines the advancing aging of the rechargeable energy storage device from a comparison of a determined future temporal change of a functional parameter of a galvanic cell to a corresponding predetermined temporal development of this functional parameter, the functional parameter comprising the measured electrical voltage of the galvanic cell;
the control apparatus comprises a second control device and a second storage unit;
the first control device is signal-connected to the second control device and the first and the second control device are arranged for sending a signal to the respective other control device and/or for receiving a signal from the respective other control device;
the first control device and the signal-connected second control device exchange at least intermittently a predetermined signal, this signal being called a “first sign of life”;
the first control device sends predetermined signals to the second control device on a regular basis and/or if required, these signals being representative of measured and/or analyzed functional parameters of the attached galvanic cells,
and/or temporal developments related to these functional parameters, and/or deviations from target values or predetermined temporal developments of these functional parameters,
and/or messages related to operational states of the attached galvanic cells,
and/or messages related to started or terminated remedy measures,
and/or messages related to the execution of an active software of the first control device,
and the second control device stores these signals in the second storage unit, preferably with at least one value which is representative of the point of time of the measurement;
the first control device or the second control device activates an electrical switching device if a first sign of life has not been received;
the second control device is arranged for reading and/or overwriting the contents of a first storage unit, whereby, for example, operational profiles for charging and/or discharging processes, predetermined temporal developments of functional parameters, target values of functional parameters and/or computing instructions are read and/or overwritten;
the second control device activates an electrical switching device if an initiated measure for recovering the adherence to a predetermined target value of a functional parameter of a galvanic cell has been unsuccessful, the functional parameter comprising the discharging current of a galvanic cell;
the second control device is signal-connected to several first control devices, at least one galvanic cell being assigned to each of these several first control devices, and such a combination of a first control device with the attached galvanic cells is called a group;
the second control device can compensate different states of charge of different galvanic cells by shifting charges between these different galvanic cells;
the control apparatus further has a switching device which is operated by the second control device, the switching device allowing for the electrical arrangement of the groups to each other as a parallel and/or serial connection or as combinations of these kinds of connections;
the second control device is at least intermittently signal-connected to at least one external control and the second control and the external control are arranged for sending a signal to the respective other control device or control and/or for receiving a signal from this respective other control device or control;
the external control is arranged for reading and/or overwriting the contents of the second storage unit, whereby in particular computing instructions, operating profiles, messages related to operational states and/or predetermined temporal developments of functional parameters of the attached galvanic cells are read and/or overwritten;
the second control device is signal-connected to at least one further control and the second control device and the further control are arranged for sending a signal to the respective other control device or control and/or for receiving a signal from this respective other control device or control;
the second control device is signal-connected to the at least one further control via an arbitrary communication bus, the communication bus being, for example, a CAN bus;
the second control device and the signal-connected further control at least intermittently exchange a predetermined signal, this signal being called “second sign of life”;
the second control device activates an electrical switching device if a second sign of life has not been received, the motor vehicle being in an operational state;
this further control activates an electrical switching device if a second sign of life has not been received;
the further control sends a predetermined signal which is called “emergency signal” to the second control device and that the second control device activates an electrical switching device when the emergency signal has been received; and
at least one galvanic cell of the rechargeable energy storage unit has a first and a second device for storing electrical charge and a means for an electrically functional connection of said devices for storing electrical charge, the means for the functional connection having electrical charge carriers which can be in particular lithium ions.

39. Method for operating a control apparatus according to claim 38, characterized in that in particular for a rechargeable energy storage unit having at least one galvanic cell, the rechargeable energy storage unit being designated in particular for the supply of an electrical drive system of a motor vehicle, characterized in that at least one first control device of the control apparatus controls a measuring device for measuring at least one functional parameter of at least one galvanic cell and an analysis device for analyzing at least one functional parameter of the at least one galvanic cell and stores the functional parameter or an entity derived from the functional parameter preferably with at least one value which is representative of the point of time of the measurement in at least one first storage unit.

40. Method for operating a control apparatus according to claim 39, characterized in that:
the first control device determines the advancing aging of the rechargeable energy storage device from a comparison of a determined future temporal change of a functional parameter of a galvanic cell to a corresponding predetermined temporal development of the functional parameter, the measured electrical voltage of the galvanic cell, for example, being used as a functional parameter;
the first control device sends predetermined signals to a second control device on a regular basis and/or if required, these signals being representative of measured and/or analyzed functional parameters of the attached galvanic cells,
and/or temporal developments related to these functional parameters,
and/or deviations from target values or predetermined temporal developments of these functional parameters,
and/or messages related to operational states of the attached galvanic cells,
and/or messages related to started or terminated remedy measures,
and/or messages related to the execution of an active software of the first control device,
and the second control device stores these signals in the second storage unit, preferably with at least one value which is representative of the point of time of the measurement;
the second control device reads and/or overwrites the contents of a first storage unit, these contents being, for instance, operational profiles for charging and/or discharging processes, predetermined temporal developments of functional parameters, target values of functional parameters and/or computing instructions;
the second control device operates a switching device for the electrical arrangement of groups, each group having a first control device and at least one galvanic cell, relative to each other as a parallel and/or serial connection or as combinations of these kinds of connection;
an external control reads and/or overwrites the contents of the second storage unit, these contents being in particular computing instructions, operational profiles, messages related to operational states and/or predetermined temporal developments of functional parameters of the attached galvanic cells;
a further control sends a predetermined signal, which is called “emergency signal”, to the second control device and that the second control device activates an electrical switching device when this emergency signal has been received; and
the first or second control device develops and/or operates a mathematical model of a control loop.
